(19) United States
(12) Patent Application Publication
(10) Pub. No.: US 2003/0091742 A1
(43) Pub. Date: May 15, 2003

(54) Coating method

(76) Inventors: Jeanne Forget, Mountain View, CA (US); Johannes Voigt, Leonberg (DE)

Correspondence Address: KENYON & KENYON, ONE BROADWAY, NEW YORK, NY, 10004, US

(21) Appl. No.: 10/149,691

(22) PCT Filed: Dec. 7, 2000
(86) PCT No.: PCT/DE00/04353

(30) Foreign Application Priority Data
Dec. 14, 1999 (DE) 199 60 092.9

(51) Int. Cl. C23C 16/00

(52) U.S. Cl. 427/255.28; 427/569; 118/723 E

(57) ABSTRACT

In a method of coating workpieces in a vacuum chamber, a workpiece is exposed to a plasma, and the resulting reaction products or decomposition products of the process gas are deposited on the workpiece. This method is characterized in that two poles, one of which is the workpiece itself or an electrode situated directly behind the workpiece and the other is a counter-electrode, are acted upon by an alternating voltage in the frequency range of 10 kHz to 100 MHz to produce the plasma between the poles, and a stream of process gas is directed onto the workpiece through an orifice in the counter-electrode.

### FIELD OF THE INVENTION

The present invention relates to a method of coating workpieces, in which a process gas in a vacuum chamber is exposed to a plasma, and the resulting reaction products or decomposition products of the process gas are deposited on the workpiece.

### BACKGROUND INFORMATION

Such methods and equipment for implementing them are conventional. In these methods, coating is usually performed at a pressure in the range of 10⁻¹ to 10⁻³ mbar, typically at a deposition rate of 1 to 2 μm per hour. Complicated installation techniques and pump systems are necessary to achieve these pressures. In addition, due to the low deposition rates, a long dwell time of the workpieces in the vacuum chamber is necessary to achieve the required layer thickness. Both factors make coating workpieces by vacuum deposition expensive.

Therefore, edge coating methods and enameling methods are also in use as less expensive alternatives. Edge coating methods produce a surface coating not by application of material but instead by conversion of the material of the workpiece at its surface to a depth of approx. 10 to a few hundred μm. It is self-evident that the chemical properties of the surface coatings producible in this manner are subject to some restrictions. In addition, it has so far been impossible to produce by this method layers having a very low friction. Microhardness values obtainable with such a method are limited to approx. 1200 to 1400 DPH.

Enameling is a very economical coating method; however, the wear resistance of enamel layers, including those based on Ormocer, is lower than that of edge layers or layers produced with the aid of plasmas.

### SUMMARY

The present invention provides a plasma coating method which permits production of layers having a good wear resistance at a high rate of deposition and with low demands regarding the vacuum chamber, and thus it is possible to greatly reduce the costs of plasma coating. These advantages may be achieved by the fact that the workpiece is acted upon by a medium- or high-frequency alternating voltage which produces the required plasma on the workpiece, and the process gas (optionally also a gas mixture) required for deposition of the layer is directed at the workpiece through an orifice in the counter-electrode.

The orifice may be configured as a nozzle which is made of a conductive material at least at the surface and may thus form an opposite electric pole to the workpiece.

In the present invention, an alternating voltage is understood to be a voltage having alternating polarities in the broadest sense, e.g., including a bipolarly pulsing direct voltage or a modulated or pulsed sinusoidal or square-wave alternating voltage, etc.

According to a first variant of the present invention, the counter-electrode is kept at ground potential and the workpiece is acted upon by an alternating potential. In a second variant, the counter-electrode is at alternating potential and the workpiece is kept at ground. There is another conceivable alternative, in which the counter-electrode and the workpiece or the electrode allocated to it are each connected to an alternating voltage without being grounded.

This method may be used at pressures of 10⁻² to 100 mbar, e.g., 10⁻¹ to 100 mbar, i.e., at much higher pressures than those traditionally used in plasma coating methods. At these pressures, the mean free path length of the residual gas in the vacuum chamber is of the same order of magnitude or smaller than its dimensions, allowing a flow to develop between the nozzle and a location in the vacuum chamber where the process gas is pumped out. To make this flow usable for the coating operation, the nozzle is oriented, or the nozzle, workpiece and pumping station are situated in such a manner that the process gas is pumped out at a location in the vacuum chamber behind the workpiece in the direction of the stream.

In addition, gas baffles may also be used to direct the gas flow at the workpiece in an even more targeted manner or to guide it around the workpiece. The flow may be optimized in this manner. It is possible to control the dwell time of the gas species in the plasma and thus the deposition rate and the layer hardness e.g., through the configuration of the gas flow and through a suitable choice of the distance between the workpiece and the electrode forming the counter-pole. The distance between the orifice in the counter-electrode and the workpiece amounts to a few millimeters to a few centimeters.

The fact that the gas flow is directional may also offer the advantage that dust particles forming in the plasma volume are transported out of the process space and thus are not allowed to be deposited on the workpiece, or the formation of dust may be suppressed entirely.

A suitable alternating voltage power is in the range of 1 to 100 watts per square centimeter of surface of workpiece to be coated.

Despite the very high deposition rate made possible with this method, very high-quality layers having a high wear resistance are obtained. Furthermore, these layers have a very low internal stress, which allows deposition of even thick layers.

Another advantage of this method is the possibility of producing a locally delimited surface coating on a workpiece with an appropriate orientation of the gas flow or configuration of the plasma volume. Two steps are eliminated in this manner in comparison with traditional methods, which provide for masking of parts of the surface that are not to be coated and removal of the mask after coating is completed.

For the most effective possible utilization of the process gas, it is expedient if the shape of the nozzle is adapted to the shape of the part of the workpiece to be coated (and also to the shape of the workpiece as a whole, if it is to be coated over the entire surface).

This adaptation may involve, for example, using a nozzle whose cross-sectional area and optionally also shape correspond to the cross section of the workpiece in the case of a single compact workpiece, using a slot-shaped nozzle in the case of an elongated workpiece or using a nozzle including a plurality of orifices for coating an arrangement of workpieces.

The ratios of the cross sections of the gas nozzle and the workpiece may be selected to be less than or greater than 1. The set area ratio influences the properties of the layer, e.g., the microhardness of the layer.

If the workpiece is conductive, it may function as the electrode which generates the plasma. If it is not conductive, a separate electrode is provided; it should be in direct contact with the workpiece, so that plasma is produced by the fields of the electrode passing through the workpiece. Plasma and electrode are then separated by the workpiece. To prevent unwanted deposition of reaction products or decomposition products of the process gas on the electrode, it may be shaped so that its active surface is covered by the workpiece and is thus shielded from reaction products or decomposition products.

The alternating voltage energizing the plasma here may have virtually any characteristic, e.g., a sinusoidal, rectangular, triangular or pulse-shaped time characteristic.

The process gas may include at least one hydrocarbon, e.g., ethylene, an organosilicon compound or an organometallic compound as the source of the layer material deposited on the workpiece. Such layer material sources allow deposition of the desired layer at process temperatures of 200° C. or less, which permits coating of workpieces from a plurality of plastic materials as well as metals and e.g., hardened steel without any loss of hardness. If the thermal stability of the workpiece is greater, so that a process temperature of approx. 400° C. or more is feasible, then other gases, e.g., halides such as TiCl₄ may also be used without diminishing the properties of the layer due to the additional incorporation of halides.

These gases may be used individually or in mixture and may also be combined with reactive gases such as O₂, N₂, H₂O₂, H₂, NH₃ and with inert gases such as Ar, He, Ne and Kr. Different layer systems are obtained, depending on the gas mixture and as a function of the change in process parameters and system configuration.

Additional features and advantages of the present invention are derived from the following description of example embodiments with reference to the figures.

### BRIEF DESCRIPTION OF THE DRAWINGS

FIG. 1 illustrates a schematic diagram of a vacuum chamber for implementation of the method according to the present invention.

FIG. 2 illustrates another example embodiment of the present invention.

FIG. 3 illustrates a refinement of the method described with respect to FIG. 2.

FIG. 4 illustrates a segment of a construction which is used in another example embodiment of the method according to the present invention.

FIG. 5 illustrates a modification of the method described with respect to FIG. 2.

### DETAILED DESCRIPTION

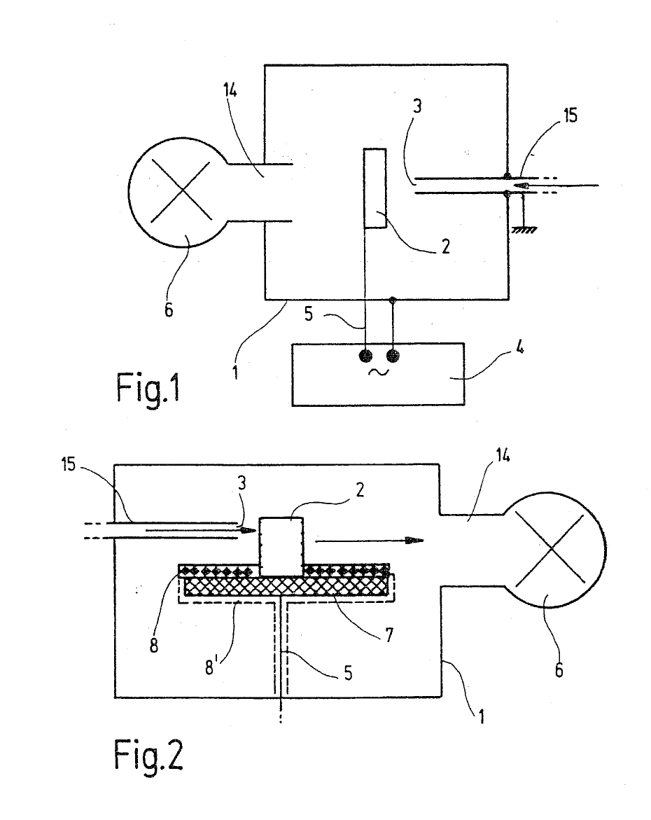

FIG. 1 illustrates schematically the principle of the present invention. A workpiece 2 to be coated is mounted in a vacuum chamber 1, its surface to be coated facing a nozzle 3, which forms the end of a supply line 15 for process gas. One pole of a high-frequency power supply 4 is connected to workpiece 2 via a line 5 and applies an alternating voltage in the frequency range of 10 kHz to 100 MHz, e.g., in the range of a few tens of MHz, to the workpiece. Workpiece 2 thus forms a first electrode.

The second pole of the high-frequency power supply is electrically connected to the metallic wall of vacuum chamber 1 and thereby to supply line 15 and is grounded jointly with these parts. Nozzle 3 thus forms a counter-electrode which is opposite workpiece 2 and makes it possible to generate a plasma in the process gas coming out of nozzle 3 in the area between nozzle 3 and workpiece 2.

In deviation from the arrangement illustrated in FIG. 1, workpiece 2 and the wall of vacuum chamber 1 may also be connected jointly to one pole of high-frequency power supply 4 and grounded, and supply line 15 and nozzle 3 are insulated electrically from chamber 1 and are connected to the second pole of high-frequency power supply 4. According to another variant, workpiece 2 and nozzle 3 as well as supply line 15 are connected to a pole of high-frequency power supply 4 and are electrically insulated from chamber 1 and are thus operated without grounding.

A pump 6 is connected to vacuum chamber 1 by a suction connection 14 which is opposite nozzle 3 and keeps its interior at a pressure in the range of 10⁻¹ to 10 mbar. A mechanical pump such as a vane-type rotary pump is sufficient for generating such a low vacuum; two-stage pump stands which also include an oil diffusion pump or a turbopump in addition to a mechanical booster pump are not necessary.

A plasma develops under the influence of the field emanating from workpiece 2, converting the process gas admitted through nozzle 3. This causes a layer to form on the workpiece. The process gas flows continuously from nozzle 3 around workpiece 2 and is pumped out by pump 6.

In a concrete application experiment, a planar component is used as workpiece 2 and is exposed to an alternating voltage of 13.56 MHz with approx. 200 W. C₂H₂ was used as the process gas, which was blown onto the surface at a flow rate of 360 sccm through perforated nozzle 3 having a diameter of 0.5 mm. The distance between nozzle 3 and the surface of workpiece 2 was 2 cm, and the pressure in the apparatus was 10⁻¹ mbar. The process temperature was approx. 150° C. An amorphous, diamond-like carbon layer (DLC) was deposited on the surface. The deposition rate was 100 μm per hour for an area of approx. 0.5 cm². Experiments with a greater distance between the nozzle and the workpiece yield lower deposition rates, as expected.

Dry friction of the layers against steel amounted to μ=0.1 to μ=0.2, comparable to high-quality DLC layers deposited by conventional methods.

The microhardness of the layer was 3600 DPH in the range of the highest deposition rate, and the modulus of elasticity of the layer was 180 megapascals (MPa). These values shown that despite the very high deposition rate, very high-quality layers having a high wear resistance are deposited.

FIG. 2 illustrates another example embodiment of the present invention. Objects already described with respect to FIG. 1 have the same reference notation and, unless otherwise indicated, have the same features as described above with respect to FIG. 1.

In the case of FIG. 2, workpiece 2 includes a cylindrical body which is placed on a plate-shaped electrode 7. This electrode connects workpiece 2 to the high-frequency power supply via line 5. A dielectric shield 8 covers the surface of the electrode facing nozzle 3, i.e., the surface which is active in generating the plasma, in all locations where it is not in contact with workpiece 2, preventing deposition of material directly on the electrode surface as well as electric arcing which may occur between ground and the surfaces exposed to alternating potential.

In a refinement of this example embodiment, dielectric shield 8′ is also provided, as illustrated with broken lines in FIG. 2. It also extends over the edges and the rear side of electrode 7, so that it is shielded on its entire surface, wherever it is not in contact with workpiece 2, and over the surface of line 5. This large-area shield yields additional protection against unwanted deposition of material and electric arcing.

C₂H₂ as the process gas was blown onto the surface of workpiece 2 at a gas flow rate of 360 sccm through perforated nozzle 3 having a diameter of 4 mm. The pressure in apparatus 1 was 2×10⁻¹ mbar. An amorphous, diamond-like carbon layer (DLC) was deposited locally on the surface of workpiece 2 in the area exposed to direct oncoming gas flow from the nozzle. The deposition rate was approx. 100 μm per hour on an area of approx. 1 cm². In the range of the highest deposition rate, the microhardness of the layer was 3200 DPH, and the modulus of elasticity of the layer was 180 gigapascals (GPa).

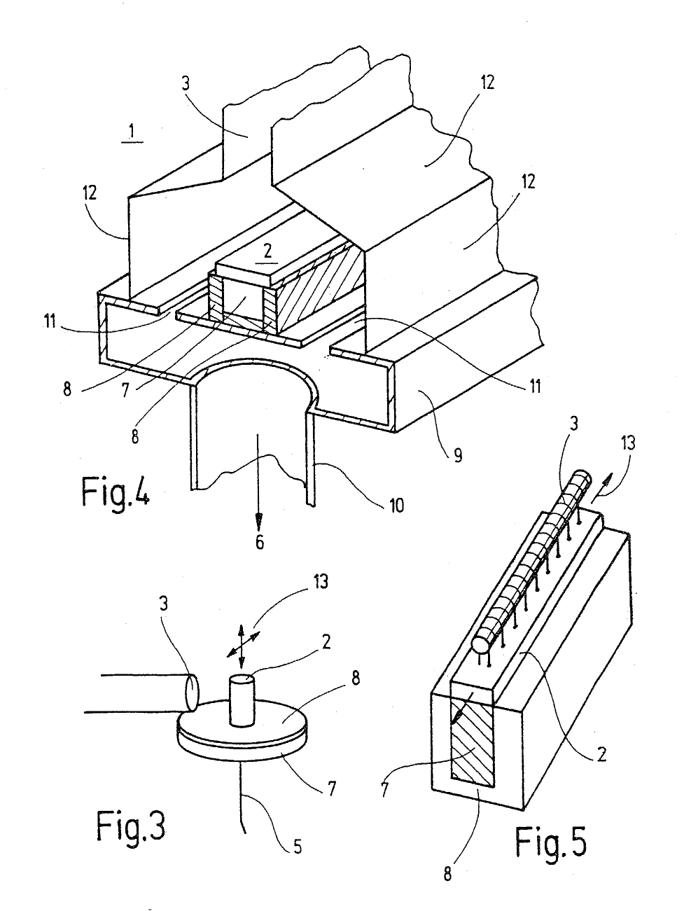

FIG. 3 illustrates a refinement of the method described with respect to FIG. 2. Electrode 8 and workpiece 2 on it rotate and may also be shifted axially as needed to coat workpiece 2 on its entire circumference or its entire free surface. It is also possible to arrange a number of workpieces 2 on electrode 7, to rotate them about their own axis as needed and to shift them tangentially toward nozzle 3 in order to coat these multiple workpieces 2 locally or allover in a method resembling a continuous operation.

FIG. 4 illustrates a segment of a construction which is used in another example embodiment of the method according to the present invention. This construction, situated in the interior of vacuum chamber 1, includes an elongated suction box 9 which is connected to pump 6 via one or more suction connections like suction connection 10 illustrated in the figure in a cutaway view. On its top side between two suction slots 11, suction box 9 includes an electrode 7 supporting a workpiece 2, as already described with respect to FIG. 2. Suction slots 11 draw the process gas out of the immediate vicinity of workpiece 2 before it is widely dispersed in the vacuum chamber.

Gas baffles 12, each sitting on the top of suction box 9 on the other side of suction slots 11, form a tunnel-like structure which is open at its end faces. On its ends facing away from suction box 9, gas baffles 12 delimit a slotted nozzle 3 extending over essentially the entire length of the structure and facing workpiece 2.

Again in this example embodiment, various options are described with respect to FIG. 1 for applying the alternating voltage to produce a plasma. Electrode 7 and workpiece 2 may be conductively connected to a pole of an alternating voltage supply whose other pole is at ground potential and is connected to nozzle 3 and to gas baffles 12, if the latter are conductive. Alternatively, the pole connected to workpiece 2 and electrode 7 may be grounded, and nozzle 3 may receive an alternating potential. Ungrounded connection of nozzle 3 as well as workpiece 2 and electrode 7 to the alternating voltage is also possible.

On its vertical side faces on the underside and the end faces, electrode 7 is provided with dielectric shields 8 which limit the plasma generated by electrode 7 to an area above workpiece 2.

Gas baffles 12 prevent an excessive distribution of the process gas in the interior of vacuum chamber 1 and direct it at the surface of workpiece 2 along suction slots 11 and thus ultimately toward pump 6. With the help of such a configuration, large workpiece surfaces may be coated rapidly with a low use of process gas.

Workpiece 2 may be secured in a stationary mount on electrode 7 or it may be moved along the electrode surface.

In the latter case e.g., slotted nozzle 3 could also be replaced by a plurality of perforated nozzles arranged in succession in the longitudinal direction of the tunnel-shaped structure. Such a structure allows the production of low-friction and wear-resistant surface layers in short process times of less than one minute in an operation which is capable of continuous flow and is thus economical.

If workpiece 2 is nonconducting, it is important for there to be a tight contact, e.g., form-fitting, between workpiece 2 and plasma electrode 7 to prevent discharges between the two.

This method and the construction are suitable e.g., for producing a wear-reducing coating on rubber parts such as windshield wipers. Such workpieces may be conveyed conveniently at the surface of the stationary electrode in the longitudinal direction of the tunnel-shaped structure, the workpieces configured in the form of a continuous strip, to coat it rapidly and economically in a continuous operation.

FIG. 5 illustrates a modification of the method described with respect to FIG. 2. A plurality of perforated nozzles 3 having a diameter of 0.8 mm distributed on a pipe which functions as a counter-electrode are used here for oncoming flow of process gas against workpiece 2. The pipe is opposite the workpiece at a distance of 10 mm. Workpiece 2 is acted upon by an alternating voltage at a frequency of 13.56 MHz and a power of approx. 10 W/cm² of surface area of workpiece 2 via an electrode 7 covered by the workpiece. The pressure in the vacuum chamber amounts to approx. 1.6 mbar. The deposition is localized on a small area of approx. 0.25 cm² opposite each nozzle 3. The deposition rate here reaches approx. 10 μm per minute at a microhardness of 1400 DPH. To achieve a homogeneous coating of the workpiece over its entire surface facing the nozzles, the workpiece is moved in front of the nozzles, as indicated by arrows 13. The movement may be in one direction, as indicated in the figure, or even in two directions, in the form of line-by-line scanning of the workpiece surface. Baffles may also be used in this modification for guiding the process gas in the environment of the workpieces.

According to another variant of the present invention, a workpiece may also be coated internally by inserting the nozzle out of which the process gas emanates, into a hollow space in the workpiece.

What is claimed is:

1. A method of coating workpieces, in which a workpiece (2) is exposed to a process gas in a vacuum chamber (1), and the resulting reaction products or decomposition products are deposited on the workpiece (2),
wherein two poles, one of which is the workpiece (2) itself and the other is a counter-electrode, are acted upon by an alternating voltage in the frequency range of 10 kHz to 100 MHz to produce the plasma between the poles, and a stream of process gas is directed onto the workpiece (2) through an orifice (3) in the counter-electrode.

2. A method of coating workpieces, in which a workpiece (2) is exposed to a process gas in a vacuum chamber (1), and the resulting reaction products or decomposition products are deposited on the workpiece (2),
wherein two poles, one of which is an electrode (7) situated directly behind the workpiece (2) and the other is a counter-electrode, are acted upon by an alternating voltage in the frequency range of 10 kHz to 100 MHz to produce the plasma between the poles, and a stream of process gas is directed onto the workpiece (2) through an orifice (3) in the counter-electrode.

3. The method according to claim 2,
wherein the workpiece (2) is electrically nonconducting.

4. The method according to claim 2 or 3,
wherein the workpiece (2) is brought into direct contact with the electrode (7), and the shape of the electrode (7) is adapted to that of the workpiece (2).

5. The method according to claim 2, 3 or 4,
wherein the workpiece (2) covers the active surface of the electrode supplied with power and shields it from the reaction products or decomposition products.

6. The method according to claim 2, 3 or 4,
wherein a dielectric shield (8) shields surface areas of the electrode not covered by the workpiece (2) from electric arcing.

7. The method according to one of the preceding claims,
wherein the workpiece (2) or the electrode (7) situated behind the workpiece (2) is acted upon by an alternating potential and the counter-electrode is kept at ground potential.

8. The method according to one of claims 1 through 6,
wherein the workpiece (2) or the electrode (7) situated behind the workpiece (2) is kept at ground potential, and the counter-electrode is acted upon by an alternating potential.

9. The method according to one of claims 1 through 6,
wherein the two poles are ungrounded.

10. The method according to one of the preceding claims,
wherein the pressure in the vacuum chamber (1) is kept between 10⁻² and 10 mbar.

11. The method according to one of the preceding claims,
wherein the power of the alternating voltage supplied is 1 to 100 W/cm² of surface area of the workpiece (2) to be coated.

12. The method according to one of the preceding claims,
wherein the alternating voltage energizing the plasma has a sinusoidal, square-wave, triangular or pulse-shaped time characteristic.

13. The method according to one of the preceding claims,
wherein the stream of the process gas is specifically directed at a portion of the surface of the workpiece (2) to coat this portion preferentially.

14. The method according to one of the preceding claims,
wherein the process gas is pumped out in the direction of the gas flow at a location (9, 14) of the vacuum chamber (1) behind the workpiece.

15. The method according to claim 14,
wherein the gas baffles (12) are used to guide the process gas around the workpiece (2).

16. The method according to one of the preceding claims,
wherein the process gas contains at least one hydrocarbon, an organosilicon compound or an organometallic compound.

17. The method according to one of claims 1 through 15,
wherein the process gas contains at least one halide.

18. The method according to one of claims 16 or 17,
wherein the process gas also contains at least one reactive gas such as O₂, N₂, H₂O₂, H₂, NH₃ or an inert gas such as a noble gas.

19. A vacuum chamber, in particular for implementing the method according to one of the preceding claims, having a chamber (1), a line (15) for supplying a process gas into the chamber (1), means for evacuating the chamber (1) and two poles which may be acted upon by an alternating voltage to generate a plasma between the poles,
wherein one pole is designed as a counter-electrode having an orifice (3), the line (15) opening at the orifice (3) and the orifice (3) being shaped to deliver a process gas stream into the chamber (1) in the direction of the other pole.

20. The vacuum chamber according to claim 19,
wherein the other pole is the workpiece (2).

21. The vacuum chamber according to claim 19,
wherein the other pole is an electrode (7) situated directly behind the workpiece (2).

22. The vacuum chamber according to one of claims 19 through 21,
wherein the shape of the orifice (3) is adapted to that of the workpiece (2) to be coated.

23. The vacuum chamber according to one of claims 19 through 22,
wherein a pumping station (9, 14) is situated behind the other pole in the chamber (1) in extension of the direction of emission of the process gas stream.

24. The vacuum chamber according to one of claims 19 through 23,
wherein gas baffles (12) are situated between the orifice (3) and the other pole.

25. The vacuum chamber according to claim 23 or 25,
wherein the gas baffles (12) form a tunnel-shaped structure for accommodating the elongated workpiece (2) or for moving it through.

26. The vacuum chamber according to one of claims 19 through 25,
wherein a suction box (9) is situated inside the chamber (1) for suction removal of the process gas from the immediate vicinity of the workpiece.
